(19) United States
(12) Patent Application Publication
(10) Pub. No.: US 2026/0223664 A1
(43) Pub. Date: Jul. 30, 2026

(54) INTERCONNECT STRUCTURE INCLUDING VERTICAL CONDUCTORS AND METHOD FOR MANUFACTURING THE SAME

(71) Applicant: TAIWAN SEMICONDUCTOR MANUFACTURING COMPANY, LTD., Hsinchu (TW)

(72) Inventors: Shu-Wei LI, Hsinchu (TW); Yu-Chen CHAN, Hsinchu (TW)

(73) Assignee: TAIWAN SEMICONDUCTOR MANUFACTURING COMPANY, LTD., Hsinchu (TW)

(21) Appl. No.: 19/036,619

(22) Filed: Jan. 24, 2025

(51) Int. Cl. H01L 23/532; H01L 21/768; H01L 23/528

(52) U.S. Cl. CPC H10W 20/4403; H10W 20/074; H10W 20/435

(57) ABSTRACT

A method for manufacturing an interconnect structure includes: forming a patterned metal layer on an upper surface of a base structure, a first conductive feature of the base structure being exposed from the patterned metal layer, the patterned metal layer having a sidewall surface extending in a first direction transverse to the upper surface of the base structure; forming a second conductive feature from the sidewall surface of the patterned metal layer, forming the second conductive feature including sequentially forming two-dimensional material layers that are arranged in a second direction transverse to the first direction; after forming the second conductive feature, performing a removing process to remove at least a portion of the patterned metal layer; and after the removing process, forming a protection layer over the second conductive feature to maintain the second conductive feature on the base structure.

### BACKGROUND

Copper with single or dual damascene structures has long been the material of choice for back-end-of-line (BEOL) interconnects in semiconductor manufacturing due to its electrical conductivity and relatively low resistivity. However, as technology nodes advance and circuit dimensions shrink, the demand for materials that can offer better performance also increases. Therefore, there is a continuous need for the development of alternative materials, advanced fabrication techniques, and innovative designs that can address the challenges of scaling, such as electromigration, resistance-capacitance (RC) delay, and power consumption, while maintaining or improving the overall performance and reliability of interconnects at smaller nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2 to 44 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

Nowadays, copper is one of the primary materials for back-end-of-line (BEOL) interconnects in semiconductor manufacturing. However, as semiconductor nodes continue to scale down, the resistivity of copper increases significantly. A new conductor that can offer better performance at the nanoscale is necessary for replacing copper, and two-dimensional (2D) materials are thus introduced due to their low resistivity sensitivity to thickness. However, major challenges in integrating 2D materials into semiconductor devices include high sheet resistance and high contact resistance between metals and the 2D materials. Overcoming these challenges is crucial for the practical application of 2D materials in BEOL interconnects, as it significantly impacts the overall device performance and energy efficiency. Therefore, the present disclosure is directed toward methods for manufacturing an interconnect structure, in which vertical 2D materials are formed, the line resistance performance in 2D materials is lowered, and the contact resistance between 2D materials and metal is reduced.

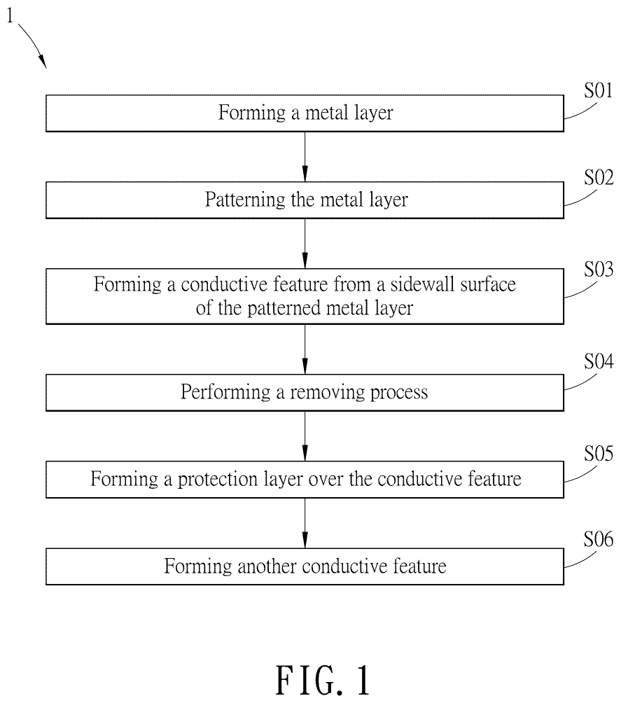

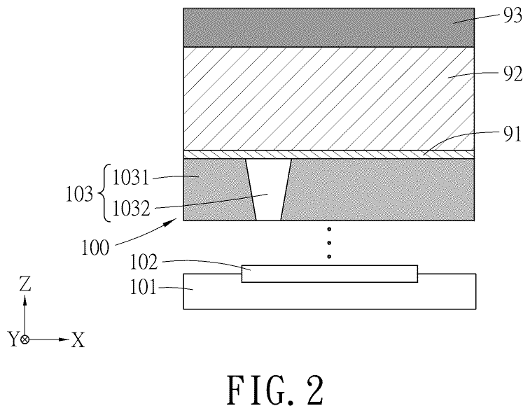

FIG. 1 is a flow diagram illustrating a method 1 for manufacturing an interconnect structure (e.g., an interconnect structure shown in FIG. 15, an interconnect structure shown in FIG. 33, or an interconnect structure shown in FIG. 44) which is formed on a base structure 100 (see FIG. 2) in accordance with some embodiments. The method 1 may include steps S01 to S06. FIGS. 2 to 44 are schematic views illustrating intermediate stages of the method 1 in accordance with some embodiments. Some repeating structures are omitted in FIGS. 2 to 44 for the sake of brevity.

Referring to FIG. 1 and the example illustrated in FIG. 2, the method 1 begins at step S01, where an adhesive layer 91, a metal layer 92, and a dielectric layer 93 are sequentially formed on an upper surface of a base structure 100. In some embodiments, the adhesive layer 91 is formed between the metal layer 92 and the base structure 100, and the metal layer 92 is formed between the adhesive layer 91 and the dielectric layer 93.

In some embodiments, the base structure 100 is a device wafer including active devices (for example, transistors, diodes, or the like), passive devices (for example, capacitors, inductors, resistors, or the like), memory devices, decoders, amplifiers, or combinations thereof. In some embodiments, the base structure 100 includes a substrate 101, a plurality of semiconductor devices 102 (one of which is exemplarily shown in FIG. 2) formed on the substrate 101, and an interconnect layer 103 formed on the semiconductor devices 102.

In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations (not shown) to separate each of the semiconductor devices 102 from adjacent ones of the semiconductor devices. In some embodiments, the trench isolations may each be a shallow trench isolation (STI), a deep trench isolation (DTI), or other suitable structures. In some embodiments, the trench isolations may include silicon oxide, silicon nitride, silicon oxynitride, other low-k (low-dielectric constant) dielectric materials, or combinations thereof.

In some embodiments, the semiconductor devices 102 may each include a transistor, but is not limited thereto. The transistor may be configured as a planar transistor, a fin-type field-effect transistor (FinFET), a gate-all-around field-effect transistor (GAAFET), a forksheet field-effect transistor, a complementary field-effect transistor (CFET), or other transistors with suitable configurations.

In some embodiments, the interconnect layer 103 includes a dielectric layer 1031 and conductive features 1032 (one of which is exemplarily shown in FIG. 2) formed in the dielectric layer 1031. The semiconductor devices 102 may be each electrically connected to an external circuit through corresponding one(s) of the conductive features 1032. In some embodiments, the dielectric layer 1031 includes or is made of a low-k dielectric material. In some embodiments, the dielectric layer 1031 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1031 are within the contemplated scope of the present disclosure. In some embodiments, the conductive features 1032 may be each configured as a conductive via which is connected to a conductive line (not shown) that is located therebeneath, and in such case, additional interconnect layer(s) (not shown) may be formed between the interconnect layer 103 and the semiconductor devices 102. In some other embodiments, the conductive features 1032 may be each configured as a conductive contact which is connected to a gate electrode or a source/drain portion of a corresponding one of the semiconductor devices 102. In some embodiments, each of the conductive features 1032 includes or is made of Co, Cu, Ni, Ru, W, Mo, Cr, Mn, Pd, Ag, Au, Ti, Al, Ir, Rh, Zr, Ta, Zn, alloys thereof, graphene, or combinations thereof. Other conductive materials suitable for the conductive features 1032 are also within the contemplated scope of the present disclosure. In some embodiments, the conductive features 1032 may be formed by a single damascene process involving physical vapor deposition (hereinafter PVD), chemical vapor deposition (hereinafter CVD), atomic layer deposition (hereinafter ALD) or other suitable processes. Hereinafter, the semiconductor devices 102 or the conductive features 1032 are described in singular form for better description.

In some embodiments, the adhesive layer 91 includes or is made of titanium, tantalum, cobalt, ruthenium, titanium nitride, tantalum nitride, tungsten carbide, or combinations thereof, and may improve adhesion between the interconnect layer 103 and the metal layer 92. In some embodiments, the adhesive layer 91 may be formed using PVD, CVD or ALD. Other materials and/or processes suitable for forming the adhesive layer 91 are also within the contemplated scope of the present disclosure.

In some embodiments, the metal layer 92 may serve as a sacrificial metal layer, and includes or is made of cobalt, ruthenium, molybdenum, tungsten, titanium, tantalum, nickel, copper, alloys thereof, or combinations thereof. In some embodiments, the metal layer 92 may be formed using PVD, CVD or ALD. Other materials and/or processes suitable for forming the metal layer 92 are also within the contemplated scope of the present disclosure.

In some embodiments, the dielectric layer 93 may be a hard mask for patterning the metal layer 92, and may include or be made of aluminum nitride, aluminum oxide, silicon oxide, silicon oxycarbide, silicon oxycarbonitride, other suitable materials, or combinations thereof. In some embodiments, the dielectric layer 93 may be formed using PVD, CVD or ALD. Other materials and/or processes suitable for forming the dielectric layer 93 are also within the contemplated scope of the present disclosure.

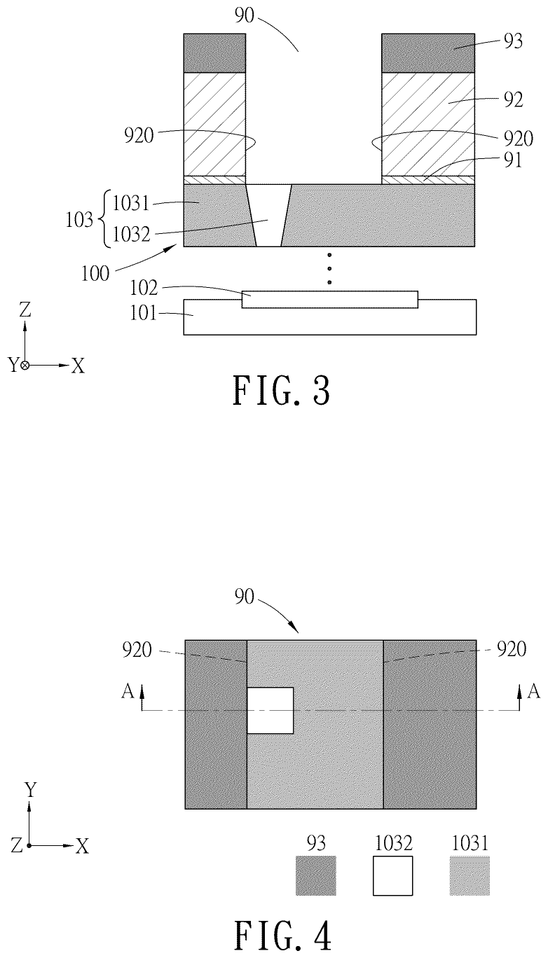

Referring to FIG. 1 and the examples illustrated in FIGS. 2 and 3, the method 1 proceeds to step S02, where a patterning process is performed to pattern the dielectric layer 93 (see FIG. 2), the metal layer 92 (see FIG. 2) and the adhesive layer 91 (see FIG. 2) so that the conductive feature 1032 of the base structure 100 is exposed from the patterned metal layer 92 (see FIG. 3). FIG. 4 is a schematic top-view diagram illustrating a positional relationship among the patterned dielectric layer 93, the dielectric layer 1031 and the conductive feature 1032 in accordance with some embodiments. FIG. 3 is a schematic sectional view (an X-cut view) taken along line A-A of FIG. 4 to illustrate the patterned adhesive layer 91, the patterned metal layer 92, the patterned dielectric layer 93, and the base structure 100 in accordance with some embodiments. In some embodiments, the patterning process may include dry etching, wet etching, or a combination thereof, and is performed to pattern the dielectric layer 93 first, and then to pattern the metal layer 92 and the adhesive layer 91 through the patterned dielectric layer 93. As shown in FIG. 3, after the patterning process, a recess 90 is formed above the conductive feature 1032, and the patterned metal layer 92 has two sidewall surfaces 920 that are spaced apart from each other in an X direction. Each of the side wall surfaces 920 extends in a Z direction transverse to the upper surface of the base structure 100. In some embodiments, the Z direction is perpendicular to the X direction. It is noted that, in some embodiments, as shown in FIG. 3, a lower end of one of the side wall surfaces 920 is spaced apart from an upper surface of the conductive feature 1032 in the X direction, and a lower end of another one of the side wall surfaces 920 is located to overlap a periphery of the upper surface of the conductive feature 1032 in the Z direction, but in some other embodiments, a positional relationship between the conductive feature 1032 and any one of the side wall surfaces 920 may be varied according to practical needs, for example, the lower end of any one of the side wall surfaces 920 may overlap with the upper surface of the conductive feature 1032 in the Z direction, or may be spaced apart from the upper surface of the conductive feature 1032 in the X direction. In addition, in FIG. 3, each of the side wall surfaces 920 is orientated orthogonal to the upper surface of the base structure 100, but in some embodiments, any one of the side wall surfaces 920 may be inclined (e.g., the recess 90 may taper toward the base structure 100), and may be a flat surface or other suitable surface topographies.

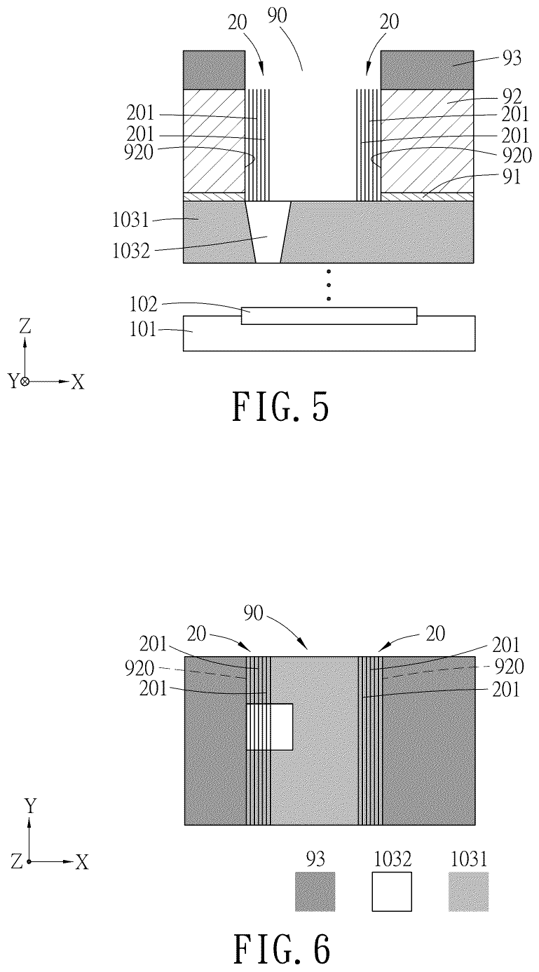

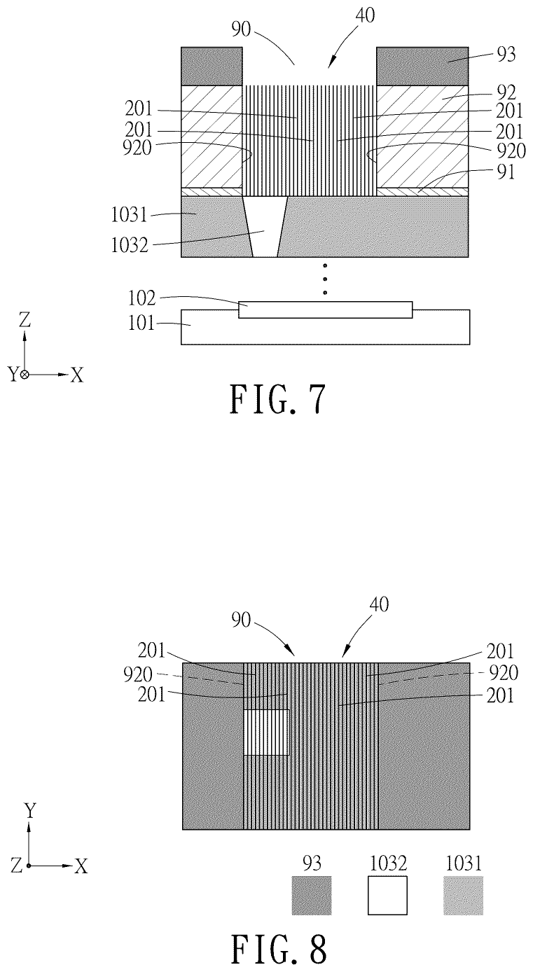

Referring to FIG. 1 and the examples illustrated in FIGS. 5 to 8, the method 1 proceeds to step S03, where two conductive features 20 are respectively formed from the two sidewall surfaces 920 of the patterned metal layer 92. Each of the two conductive features 20 includes two-dimensional (2D) material layers 201. FIGS. 5 and 7 are each an X-cut view subsequent to FIG. 3 and illustrate two possible intermediate stages in step S03 in accordance with some embodiments. FIGS. 6 and 8 are respectively schematic top-view diagrams of FIGS. 5 and 7 for illustrating the two possible intermediate stages subsequent to FIG. 4 in accordance with some embodiments. In some embodiments, step S03 may include multiple sub-steps as described in the following.

Firstly, as shown in FIG. 5, the 2D material layers 201 of each one of the two conductive features 20 are sequentially formed on the respective one of the sidewall surfaces 920 of the patterned metal layer 92, are arranged in the X direction, and are located in the recess 90.

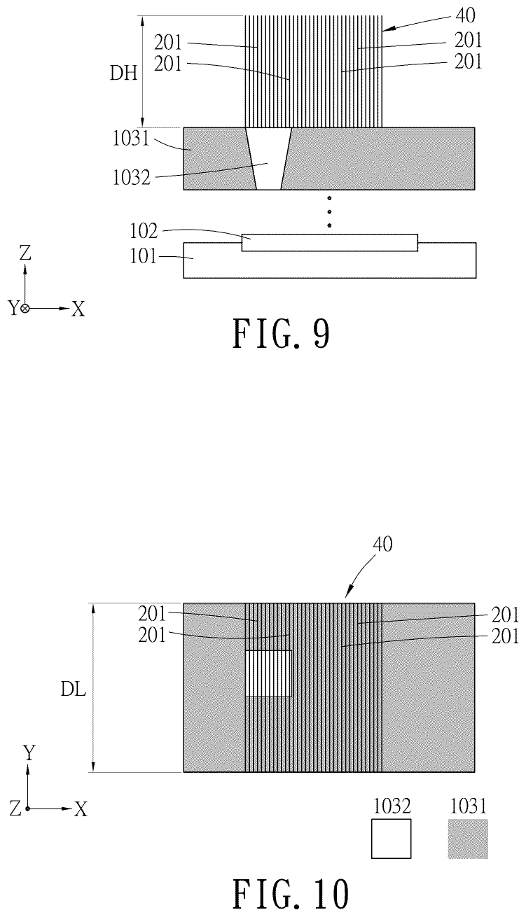

Then, as shown in FIG. 7, the formation of each of the conductive features 20 (see FIG. 5) stops when one of the 2D material layers 201 of one of the conductive features 20 (see FIG. 5) meets one of the 2D material layers 201 of another one of the conductive features 20 (see FIG. 5). At this time, the conductive features 20 (see FIG. 5) located between the sidewall surfaces 920 of the patterned metal layer 92 in the X direction are connected to each other to form a combined conductive feature 40 in which the 2D material layers 201 are arranged in the X direction, and the combined conductive feature 40 is formed on the conductive feature 1032. Consequently, as shown in FIGS. 7 and 8, in some embodiments, the combined conductive feature 40 is configured as a conductive line (which is also denoted by 40) above the conductive feature 1032. In some embodiments, the conductive line 40 has a thickness (DH; measured in the Z direction, see FIG. 9) ranging from about 3 Å to about 300 Å, but other ranges of values are also within the contemplated scope of the present disclosure. In some embodiments, the conductive line 40 has a length (DL; measured in the X direction, or in a Y direction transverse to the Z direction and the X direction, see FIG. 10) ranging from about 5 Å to about 500 Å, but other ranges of values are also within the contemplated scope of the present disclosure. For example, in the case that the 2D material layers 201 are made of graphene and the conductive line 40 includes only one 2D material layer 201, a minimum thickness (measured in the Z direction) of the conductive line 40 may reach about 3 Å.

In some embodiments, the combined conductive feature 40 (i.e., each of the conductive features 20; see FIG. 5) may include or be made of a 2D conductive material, such as graphene, intercalated graphene, N-doped graphene, O-doped graphene, modified graphene, hexagonal boron nitride (h-BN), intercalated h-BN, N-doped h-BN, O-doped h-BN, modified h-BN, boroncarbonitride (BCN), transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, or combinations thereof. The N-doped or O-doped 2D conductive material means that some elements of the 2D material are replaced by nitrogen or oxygen elements. For example, N-doped or O-doped graphene means that some carbon elements in graphene are replaced by nitrogen or oxygen elements. The TMD may be 2D TMD, and includes a transition metal (e.g., Zr, Ta, Nb, Hf, W, Mo, Ga, Sn, etc.) and a chalcogenide (Se, S, Te, etc.). In some embodiments, the TMD includes MoS₂, TaS₂, HfS₂, WSe₂, or combinations thereof. The 2D metal includes a single metal element, and the 2D alloy includes at least two metal elements. In some embodiments, metal elements suitable for forming the 2D metal (or 2D alloy) includes Al, Fe, Co, Ni, Cu, Ru, Rh, Pd, Ag, Sn, Sb, Ir, Pt, Au, Pb, Bi, or combinations thereof. It is noted that the electronic properties of the 2D TMD are quite different from the electronic properties of a bulk TMD. For example, although the bulk TMD serving as a semiconductor material has a relatively low electrical conductivity, the electrical conductivity of the 2D TMD is high enough to allow the 2D TMD to be formed as conductive lines (e.g., the combined conductive feature 40 and the conductive features 20) in an interconnecting structure. Other suitable 2D conductive materials are within the contemplated scope of the present disclosure.

In some embodiments, formation of the combined conductive feature 40 may include forming the 2D material layers 201 of the conductive features 20 (see FIG. 5; which may include or be made of graphene, h-BN, TMD, 2D TMD, germanane, Ni3(HITP)2, 2D metal, 2D alloy, other suitable 2D conductive materials or combinations thereof), followed by performing a treatment to the 2D material layers 201. The treatment may be one of a plasma treatment, CVD, plasma-enhanced CVD (hereinafter PECVD), ALD, a soaking treatment, supercritical fluid treatment, or combinations thereof. In some embodiments, the treatment is performed to introduce an intercalant into spaces among the 2D material layers 201 (to form intercalated 2D material), to graft functional groups to the 2D material layers 201 (to form modified 2D material), or to replace some elements (e.g., carbon elements) in the 2D material layers 201 with functional groups (to form modified 2D material). In some embodiments, the treatment is performed to introduce the intercalant into the spaces among the 2D material layers 201, to graft the functional groups to the 2D material layers 201 and to replace some elements in the 2D material layers 201 with the functional groups. In some embodiments, the intercalant may include metal ions, an organic compound, an inorganic compound, a macromolecule, or combinations thereof. In some embodiments, the metal ions may include lithium ions, potassium ions, caesium ions, sodium ions, or combinations thereof. In some embodiments, the metal ions may be introduced into the spaces among the 2D material layers 201 by soaking a solution including the metal ions or other suitable processes. In some embodiments, the organic compound may include benzene, pyridine, furan, catechol, or combinations thereof. In some embodiments, the inorganic compound includes FeCl₃, MoCl₅, AuCl₃, CuCl₂, H₂SO₄, AlCl₃, Br₂, Cl₂, HNO₃, or combinations thereof. In some embodiments, the macromolecule may be a polymer or an oligomer, and may include polymethyl methacrylate, polymethyl methacrylate oligomer, polystyrene, polystyrene oligomer, polycaprolactam, polycaprolactam oligomer, or combinations thereof. In some embodiments, the functional groups may include sulfate groups, phosphate groups, carboxyl groups, nitrate groups, amino groups, amine groups, or combinations thereof. For example, in the case that the 2D material layers 201 are made of graphene, the treatment results in the formation of sulfate-modified graphene, phosphate-modified graphene, carboxyl-modified graphene, nitrate-modified graphene, ammonia-modified graphene, other suitable functional group-modified graphene or combinations thereof. In some other embodiments, formation of the combined conductive feature 40 includes forming the 2D material layers 201 of the conductive features 20 by using first precursor(s) for forming the 2D material layers 201 and second precursor(s) for introducing the intercalant into the 2D material layers 201 and/or modifying the 2D material layers 201, and therefore the above treatment may be not necessary after forming the 2D material layers 201. In some embodiment, the intercalant may be introduced into the 2D material layers 201 by alternately forming a layer of the 2D conductive material and a layer of the intercalant. In certain embodiments, formation of the combined conductive feature 40 includes forming the 2D material layers 201 of the conductive features 20 (see FIG. 5) by using the first precursor(s) and the second precursor(s), and performing the above treatment to further introduce the intercalant into the spaces among the 2D material layers 201 and/or to graft the functional groups to the 2D material layers 201. The 2D material layers 201 may have increased conductivity by introducing the intercalant into the spaces among the 2D material layers 201, and/or by grating the functional groups to the 2D material layers 201.

Referring to FIG. 1 and the examples illustrated in FIGS. 9 and 10, the method 1 proceeds to step S04, where a removing process is performed after the formation of the combined conductive feature 40 to remove the patterned metal layer 92 (see FIG. 7). Specifically, as shown in FIG. 9, the patterned dielectric layer 93 (see FIG. 7), the patterned adhesive layer 91 (see FIG. 7), and the patterned metal layer 92 (see FIG. 7) are all removed. FIGS. 9 and 10 are schematic diagrams respectively subsequent to FIGS. 7 and 8 but illustrating the structure after step S04 in accordance with some embodiments. The removing process may be performed using a suitable etching process, such as dry etching, wet etching, an ashing process, other suitable processes, or combinations thereof, so as to obtain a structure as illustrated in FIGS. 9 and 10. In the embodiment shown in FIGS. 9 and 10, the patterned metal layer 92 (see FIG. 7) is fully removed. However, in some embodiments, the patterned metal layer 92 (see FIG. 7) may not be fully removed (i.e., a portion of the patterned metal layer 92 is removed while another portion of the patterned metal layer 92 is not removed). In some other embodiments not shown, the interconnect layer 103 shown in FIG. 2 may be omitted and the combined conductive feature 40 may be formed directly on the semiconductor device 102 to serve as a gate contact (connected to a gate electrode of the semiconductor device 102) or a source/drain contact (connected to a source/drain contact of the semiconductor device 102). In some other embodiments, the combined conductive feature 40 may serve as other conductive via or line in the BEOL.

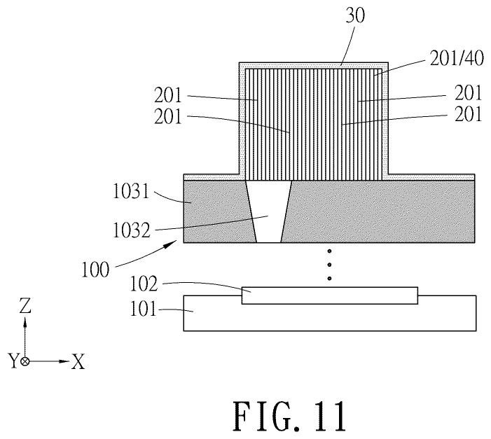

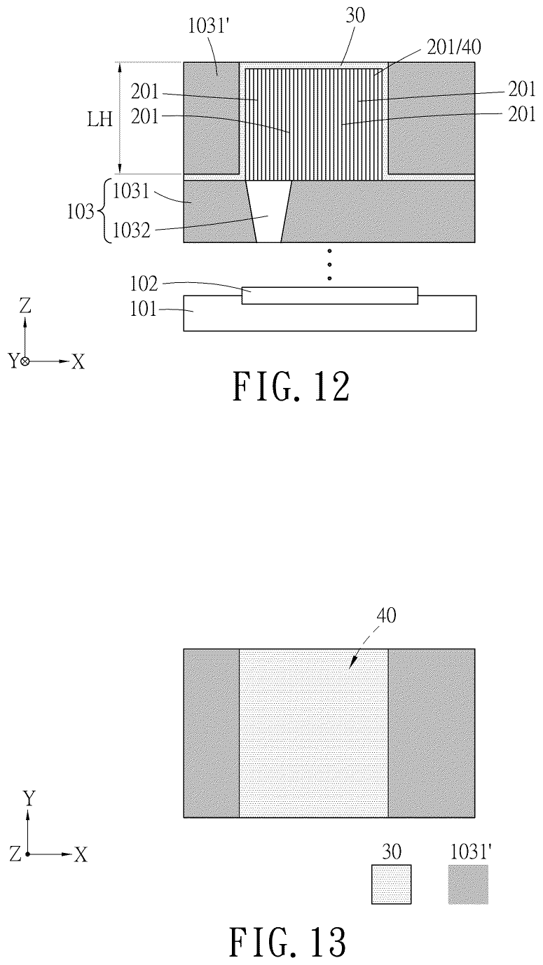

Referring to FIG. 1 and the examples illustrated in FIGS. 11 to 14, the method 1 proceeds to step S05, where a protection layer 30 is formed over the combined conductive feature 40 to maintain the combined conductive feature 40 on the base structure 100 (see FIG. 11). FIGS. 11, 12, and 14 are each an X-cut view subsequent to FIG. 9 and illustrate three possible intermediate stages in step S05 in accordance with some embodiments. FIG. 13 is a schematic top-view diagram of FIG. 12 for illustrating the intermediate stage subsequent to FIG. 10 in accordance with some embodiments. In some embodiments, step S05 may include multiple sub-steps as described in the following.

First, referring to FIG. 11, the protection layer 30 is formed over the combined conductive feature 40 and the dielectric layer 1031. In some embodiments, the protection layer 30 may be formed by ALD, molecular layer deposition (hereinafter MLD), other suitable processes, or combinations thereof. In some embodiments, the protection layer 30 may include or be made of a liner material, a barrier material, or a combination thereof. The liner material may be selected from cobalt, ruthenium, manganese, zinc, zirconium, tungsten, molybdenum, osmium, iridium, aluminum, iron, nickel, alloys thereof, nitrides thereof, oxides thereof, or combinations thereof. The barrier material may be selected from aluminum nitride, aluminum oxide, silicon oxide, silicon oxycarbide, silicon oxycarbonitride, or combinations thereof. It is noted that the combined conductive feature 40 in a nanoscale may be liable to shift or detach from the base structure 100, or to be damaged in subsequent processes. With provision of the protection layer 30, it is useful to maintain the combined conductive feature 40 on the base structure 100. To be specific, the barrier material is used for preventing the combined conductive feature 40 from moisture or damage caused by subsequent processes, and for protecting the combined conductive feature 40 from oxidation. The liner material is used for pressing and positioning the combined conductive feature 40 on the dielectric layer 1031 so that the combined conductive feature 40 is less likely to move relative to the dielectric layer 1031.

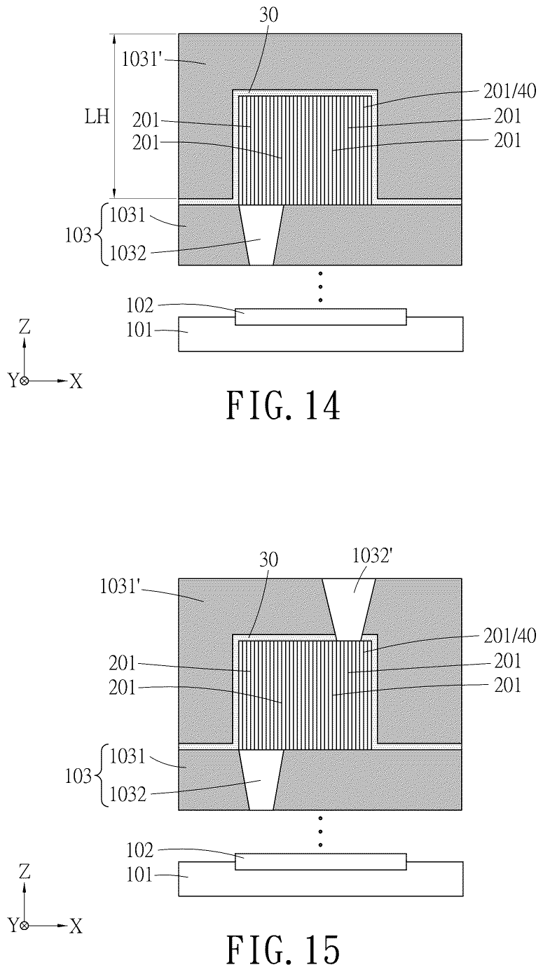

Afterwards, referring to FIGS. 12 and 13, a lower sublayer of the low-k dielectric layer 1031′ is formed above a portion of the protection layer 30 such that an upper surface of the lower sublayer of the low-k dielectric layer 1031′ is substantially at a same height (measured in the Z direction) as an upper surface of the protection layer 30 that is located on the combined conductive feature 40. The lower sublayer of the low-k dielectric layer 1031′ may be formed by depositing a dielectric material of the lower sublayer using a suitable deposition process such as CVD, ALD, a thermal process, a spin-coating process, a spin-on process, or other suitable processes, followed by removing an excess of the dielectric material using, for example, chemical mechanical polishing (CMP), to expose the upper surface of the protection layer 30. Then, referring to FIG. 14, an upper sublayer of the low-k dielectric layer 1031′ is formed over the lower sublayer thereof and the upper surface of the protection layer 30 using a suitable disposition process such that the protection layer 30 is covered by the low-k dielectric layer 1031′. It is noted that, in some embodiments, the low-k dielectric layer 1031′ may be directly formed at once to cover the protection layer 30 by depositing a dielectric material for forming the low-k dielectric layer 1031′ followed by removing an excess of the dielectric material (e.g., by CMP) until the low-k dielectric layer 1031′ has a predetermined thickness (e.g., LH shown in FIG. 14). In some embodiments, the thickness (LH) of the low-k dielectric layer 1031′ (measured in the Z direction) ranges from about 3 Å to about 500 Å, but other ranges of values are also within the contemplated scope of the present disclosure. In some embodiments, the low-k dielectric layer 1031′ may include Si, C, O and H. In some embodiments, the low-k dielectric layer 1031′ includes or is made of silicon oxide, silicon nitride, silicon oxycarbide (which may be also referred to as oxygen-doped siliconcarbide, abbreviated as ODC or SiOC), silicon oxynitride (SiON), silicon carbon oxynitride, silicon carbon nitride (which may be also referred to as nitrogen-doped silicon carbide, abbreviated as NDC or SiCN), silicon oxide formed from tetraethoxysilane (TEOS), or combinations thereof. Other low-k dielectric materials suitable for the low-k dielectric layer 1031′ are within the contemplated scope of the present disclosure. The dielectric constant value for the low-k dielectric layer 1031′ ranges from about 1.5 to about 3.9, but other ranges of values are also within the contemplated scope of the present disclosure.

Referring to FIG. 1 and the example illustrated in FIG. 15, the method 1 proceeds to step S06, where a conductive feature 1032′ is formed to penetrate through the low-k dielectric layer 1031′ and the protection layer 30 and to be in contact with the combined conductive feature 40. FIG. 15 is an X-cut view subsequent to FIG. 14 for illustrating the structure obtained in step S06 in accordance with some embodiments. Suitable materials and processes for forming the conductive feature 1032′ are similar to those for forming the conductive feature 1032 described with reference to FIG. 2, and thus the details thereof are omitted for the sake of brevity. In some embodiments, the conductive feature 1032′ may be configured as a conductive via which is connected to the conductive line (i.e., the combined conductive feature 40) that is located therebeneath.

In some embodiments, some steps in the method 1 may be modified, replaced, or eliminated without departure from the spirit and scope of the present disclosure. In some alternative embodiments, the interconnecting structure may further include additional features, and/or some features present in the interconnect structure may be modified, replaced, or eliminated without departure from the spirit and scope of the present disclosure. The method 1 illustrated by FIG. 1 may be applied for forming another interconnect structure in which the materials used therein and/or the aspect ratio and/or the pitch of the conductive lines/vias are different from those illustrated in steps S01 to S06. The method 1 illustrated by FIG. 1 may further be applied to a semiconductor manufacturing process that uses 20 nanometer technology, or technology involving a dimension greater/smaller than 20 nanometer. Furthermore, other techniques suitable for forming 2D material layers in the interconnect structure may be integrated into the method of this disclosure.

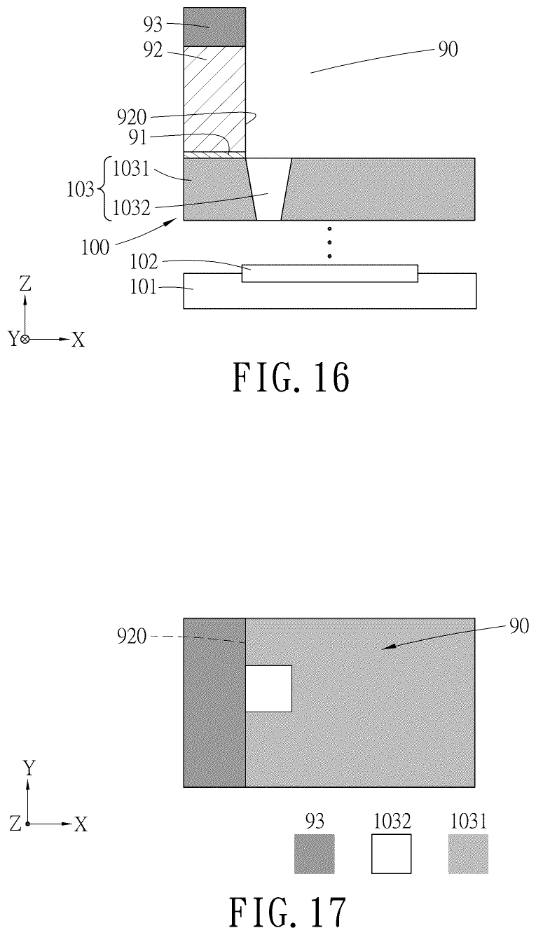

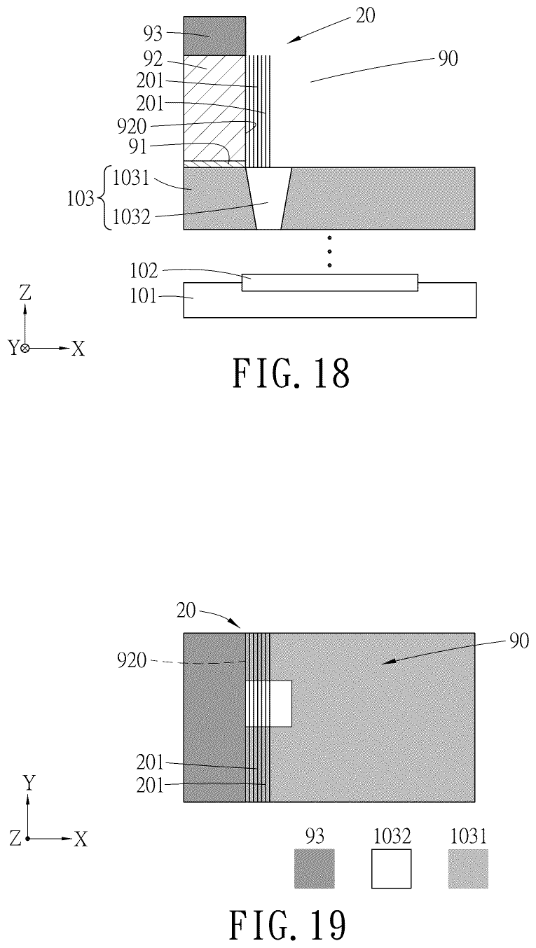

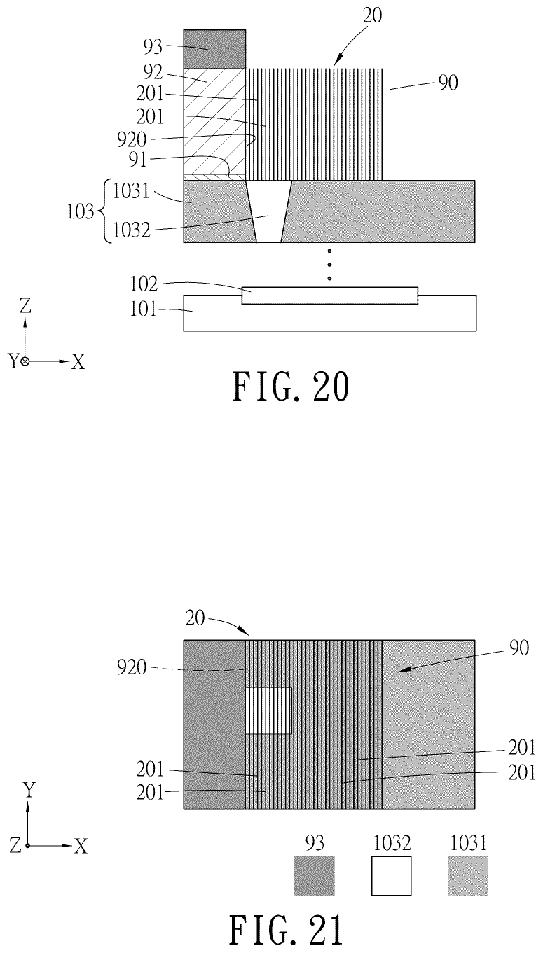

For example, in some embodiments, the adhesive layer 91, the metal layer 92 and the dielectric layer 93 shown in FIG. 2 are patterned in a different manner to obtain the structure shown in FIG. 16. FIGS. 16 to 21 are schematic views that are respectively similar to those of FIGS. 3 to 8, except that the patterned metal layer 92 has only one sidewall surface 920 in the recess 90, that only one conductive feature 20 shown in FIGS. 18 and 19 is formed from the sidewall surface 920, and that a dimension of the conductive feature 20 in the X direction is controlled by the time for growing the 2D material layers 201. Unless otherwise specified, details of the processes in achieving the structures of FIGS. 16 to 21 are similar to those described with reference to FIGS. 3 to 8, and thus details thereof are omitted for the sake of brevity. After the structure of each of FIGS. 20 and 21 is achieved, the method 1 proceeds to subsequent steps as shown in the examples illustrated in FIGS. 9 to 15.

Referring to FIGS. 16 and 17, different from the example illustrated in FIGS. 3 and 4, in step S02, the adhesive layer 91, the metal layer 92 and the dielectric layer 93 shown in FIG. 2 are patterned such that the patterned adhesive layer 91, the patterned metal layer 92 and the patterned dielectric layer 93 are only located at one side of the conductive feature 1032, and that the recess 90 is not located between two sidewall surfaces 920 (see FIGS. 3 and 4).

Referring to FIGS. 18 and 19, different from the example illustrated in FIGS. 5 and 6, in step S03, only one conductive feature 20 is formed from the sidewall surface 920.

Referring to FIGS. 20 and 21, different from the example illustrated in FIGS. 7 and 8, in step S03, the formation of the conductive feature 20 stops after the predetermined time. When the formation of the conductive feature 20 stops, the formation is completed.

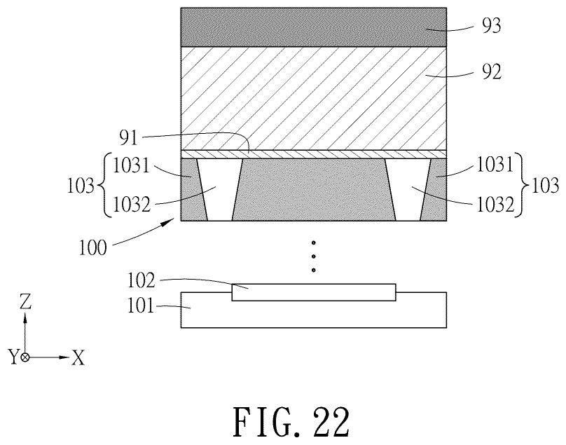

In some other embodiments, the method 1 may be used for forming two conductive features 20, which are spaced apart from each other, respectively formed on two conductive features 1032 of the interconnect layer 103, and such method 1 may also be illustrated by FIGS. 22 to 33. Unless otherwise specified, details of the processes in achieving the structures of FIGS. 22 to 33 are similar to those described with reference to FIGS. 2 to 15, and thus details thereof are omitted for the sake of brevity.

FIG. 22 illustrates a structure obtained in step S01 in accordance with some embodiments. FIG. 22 is a diagram similar to FIG. 2 except that two of the conductive features 1032 of the interconnect layer 103 are exemplarily shown.

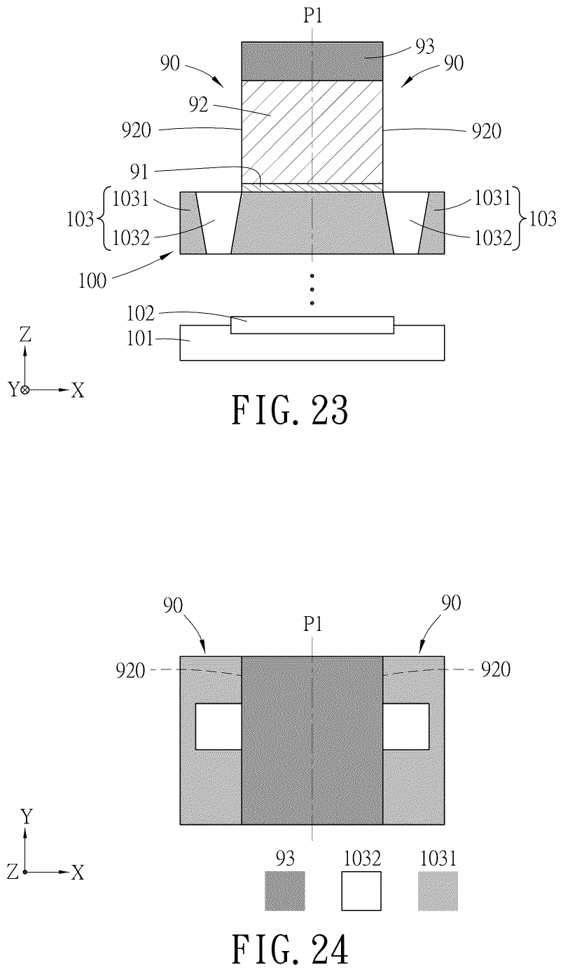

FIGS. 23 and 24 illustrate a structure obtained in step S02 in accordance with some embodiments. FIGS. 23 and 24 are diagrams respectively similar to FIGS. 3 and 4, except that FIGS. 23 and 24 show a structure subsequent to FIG. 22, and illustrate that, in step S02, the adhesive layer 91, the metal layer 92 and the dielectric layer 93 shown in FIG. 22 are patterned such that the two sidewall surfaces 920 of the patterned metal layer 92 are located between the two conductive features 1032 in the X direction, and that two recesses 90 are formed, respectively bordered by the two sidewall surfaces 920, and respectively located on the conductive features 1032.

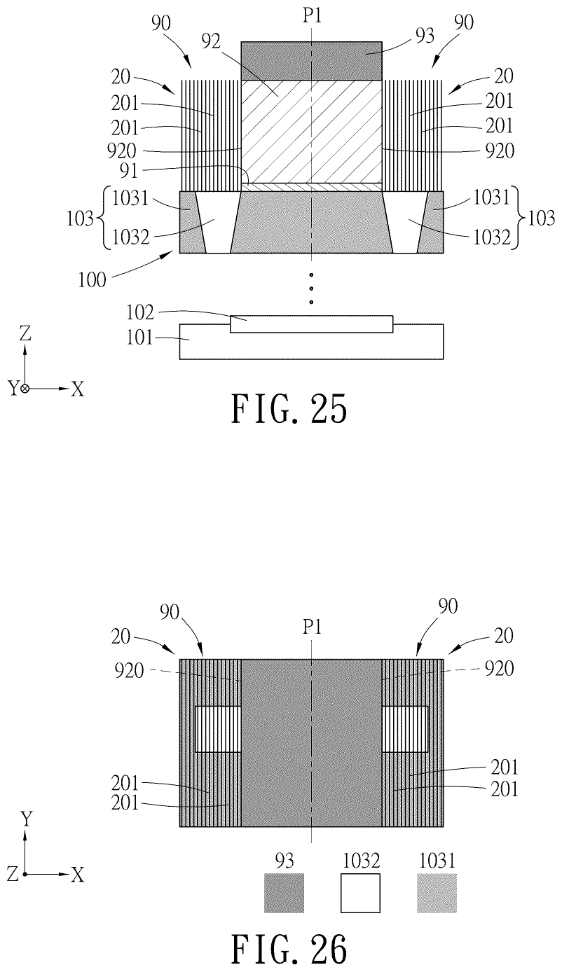

FIGS. 25 and 26 illustrate a structure obtained in step S03 in accordance with some embodiments. FIGS. 25 and 26 are diagrams respectively similar to FIGS. 7 and 8, except that FIGS. 25 and 26 show a structure subsequent to FIGS. 23 and 24, and illustrate that the two conductive features 20 are spaced apart from each other (i.e., the combined conductive feature 40 shown in FIGS. 7 and 8 is not obtained). Referring to FIGS. 25 and 26, in step S03, the two conductive features 20 are formed away from each other (i.e., in a left-right direction of FIG. 25, growth of the formation of the left conductive feature 20 advances away from the right conductive feature 20, and growth of the formation of the right conductive feature 20 advances away from the left conductive feature 20), and the two sidewall surfaces 920 of the patterned metal layer 92 are located between the two conductive features 20 in the X direction.

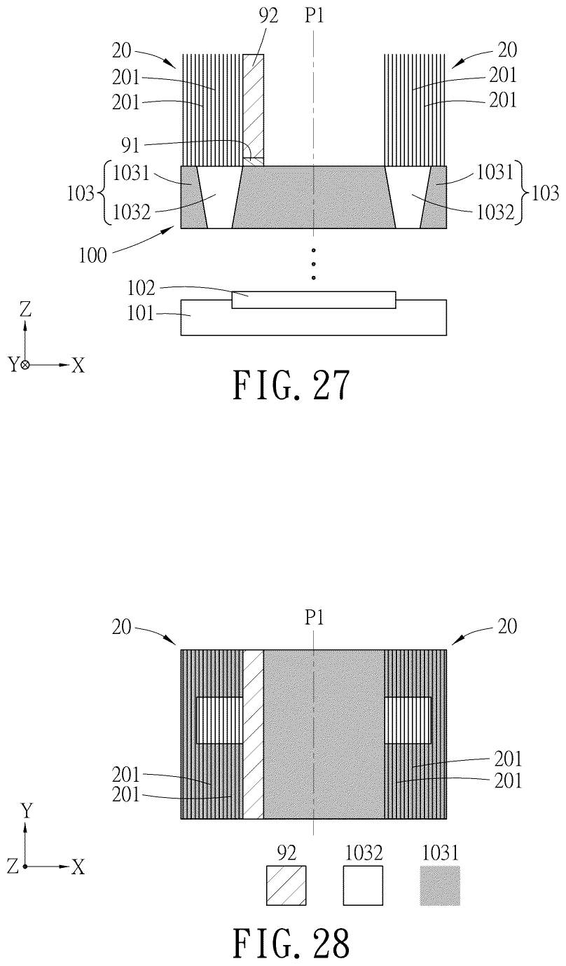

FIGS. 27 and 28 illustrate a structure obtained in step S04 in accordance with some embodiments. FIGS. 27 and 28 are diagrams respectively similar to FIGS. 9 and 10, except that FIGS. 27 and 28 show a structure subsequent to FIGS. 25 and 26, and illustrate that, in step S04, the adhesive layer 91 and the patterned metal layer 92 are not fully removed. In some embodiments, a remaining material (which may be also referred to as a remaining metal material and which includes a remaining portion of the adhesive layer 91 and a remaining portion of the patterned metal layer 92) remains on one of the conductive features 20. However, in some other embodiments, the remaining material may remain on both of the conductive features 20. The remaining material may increase conductivity of the conductive feature(s) 20 on which it remains. In some embodiments, the remaining metal material is in a form of a continuous layer (see FIG. 27). However, in some other embodiments, the remaining metal material may be in a form of a discontinuous layer or particles (not shown). Each of the conductive features 20 has a downward surface connected to the upper surface of the base structure 100, an upward surface opposite to the downward surface, and an interconnection surface which interconnects the upward surface and the downward surface. The remaining metal material may remain on the interconnection surface of one or both of the conductive features 20.

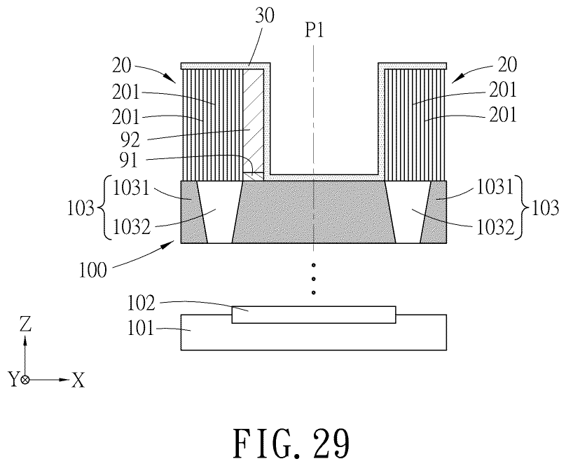

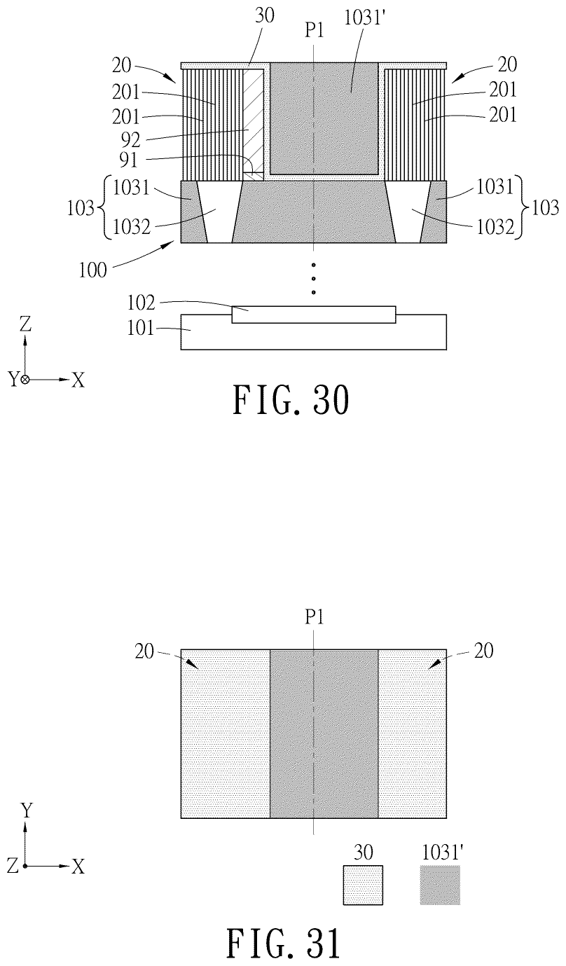

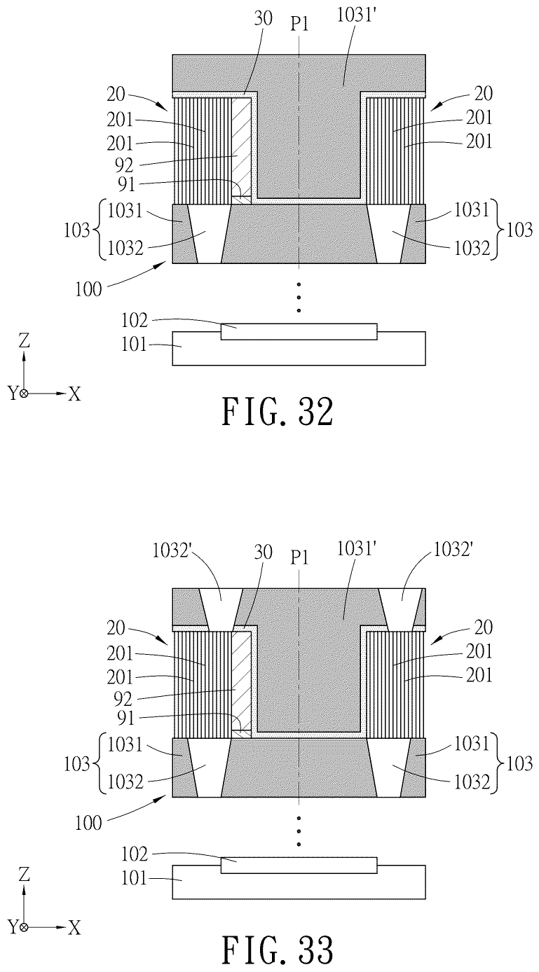

FIGS. 29 and 30 respectively illustrate two possible intermediate stage of step S05 in accordance with some embodiments. FIGS. 29 and 30 are diagrams respectively similar to FIGS. 11 and 12, except that FIGS. 29 and 30 show two structures subsequent to FIG. 27. In FIG. 29, the protection layer 30 is formed over the conductive features 20 and the remaining metal material to maintain the conductive features 20 and the remaining metal material on the base structure 100. In some embodiments, the remaining metal material is located between the protection layer 30 and at least one of the conductive features 20. FIG. 31 is a top schematic top-view diagram of FIG. 30 for illustrating the intermediate stage subsequent to FIG. 28 in accordance with some embodiments. FIG. 32 is a diagram similar to FIG. 14 for illustrating an intermediate stage of step S05 subsequent to FIG. 30 in accordance with some embodiments.

FIG. 33 illustrates a structure obtained in step S06 in accordance with some embodiments. FIG. 33 is a diagram similar to FIG. 15, except that FIG. 33 shows a structure subsequent to FIG. 32, and illustrate that, in step S06, two conductive features 1032′ are formed to penetrate through the low-k dielectric layer 1031′ and the protection layer 30 and to be respectively connected to the conductive features 20 that are located therebeneath, and one of the conductive features 1032′ is further connected to the remaining portion of the patterned metal layer 92. In some other embodiments not shown, the number of the conductive features 1032′ (each extending through the low-k dielectric layer 1031′ and the protection layer 30) may be more than two, and two of the conductive features 1032′ may both be connected to only one of the conductive features 20. It is noted that, for a better understanding, referring to FIGS. 23 to 26, when each of the examples illustrated in FIGS. 23 to 26 is cut by an imaginary plane (P1) and only a portion of each example that is located at a right side of the imaginary plane (P1) remains, the structure above the base structure 100 in each of FIGS. 23 to 26 may become substantially the same as that in a corresponding one of FIGS. 16, 17, 20 and 21.

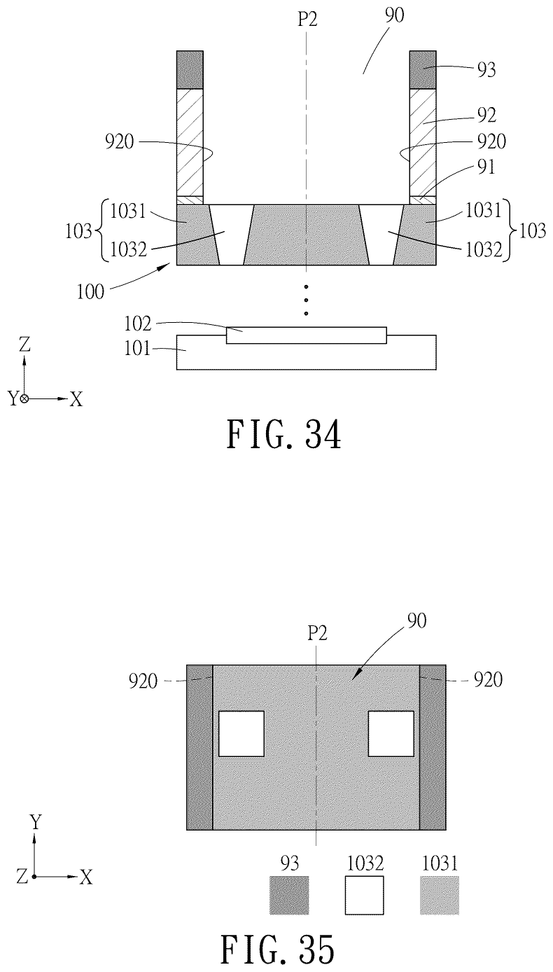

In certain embodiments, the method 1 may be used for forming the two spaced-apart conductive features 20 in a manner different from that illustrated by FIGS. 23 to 33, and such method 1 may also be illustrated by FIGS. 34 to 44. Unless otherwise specified, details of the processes for achieving the structures of FIGS. 34 to 44 are similar to those described with reference to FIGS. 23 to 33, and thus details thereof are omitted for the sake of brevity.

FIGS. 34 and 35 illustrate a structure obtained in step S02 in accordance with some embodiments. FIGS. 34 and 35 are diagrams respectively similar to FIGS. 23 and 24, except that FIGS. 34 and 35 illustrate that, in step S02, the adhesive layer 91, the metal layer 92 and the dielectric layer 93 are patterned such that the two conductive features 1032 are located between the two sidewall surfaces 920 of the patterned metal layer 92 in the X direction, that each of the conductive features 1032 is spaced apart from an adjacent one of the sidewall surfaces 920 in the X direction, and that only one recess 90 is formed between the two sidewall surfaces 920 and on the conductive features 1032.

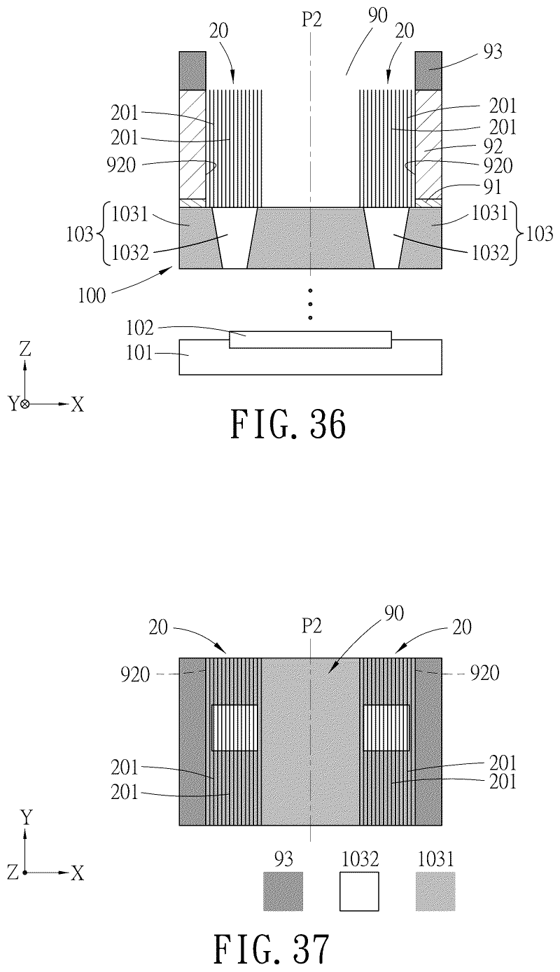

FIGS. 36 and 37 illustrate a structure obtained in step S03 in accordance with some embodiments. FIGS. 36 and 37 are diagrams respectively similar to FIGS. 25 and 26, except that FIGS. 36 and 37 show a structure subsequent to FIGS. 34 and 35, and illustrate that, in step S03, the two conductive features 20 are formed toward each other (i.e., in a left-right direction of FIG. 36, growth of the formation of the left conductive feature 20 advances towards the right conductive feature 20, and growth of the formation of the right conductive feature 20 advances towards the left the conductive features 20). In addition, a dimension of each of the conductive features 20 in the X direction is controlled by the time for growing the 2D material layers 201 of the each of the conductive features 20 (i.e., the formation of each of the conductive features 20 stops when the each of the conductive features 20 has grown to reach a predetermined dimension thereof). The two conductive features 20 are located between the two sidewall surfaces 920 of the patterned metal layer 92 in the X direction and are separated from each other.

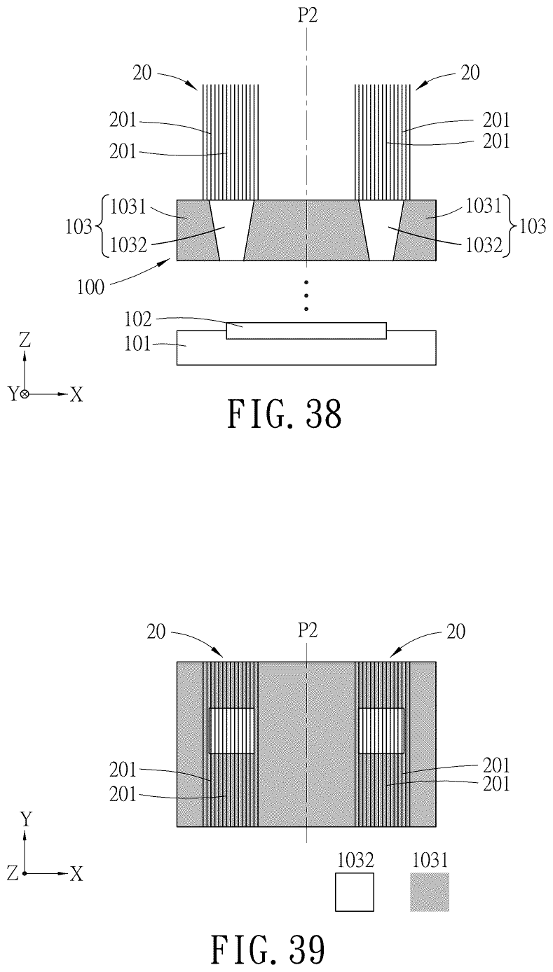

FIGS. 38 and 39 illustrate a structure obtained in step S04 in accordance with some embodiments. FIGS. 38 and 39 are diagrams respectively similar to FIGS. 27 and 28, except that FIGS. 38 and 39 show a structure subsequent to FIGS. 36 and 37, and illustrate that, in step S04, the adhesive layer 91 and the patterned metal layer 92 are fully removed, and each of the two conductive features 20 is not in contact with anything in the X direction.

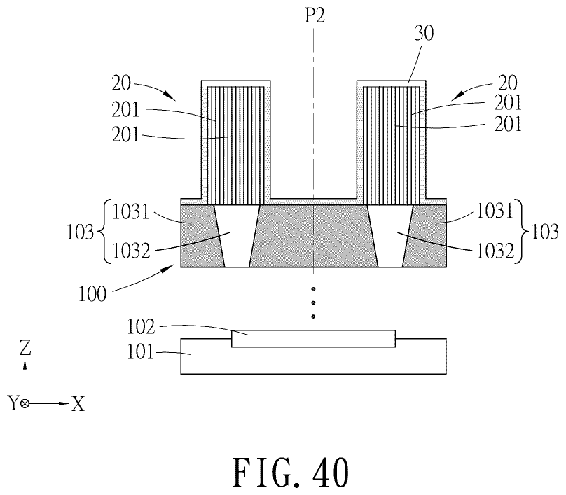

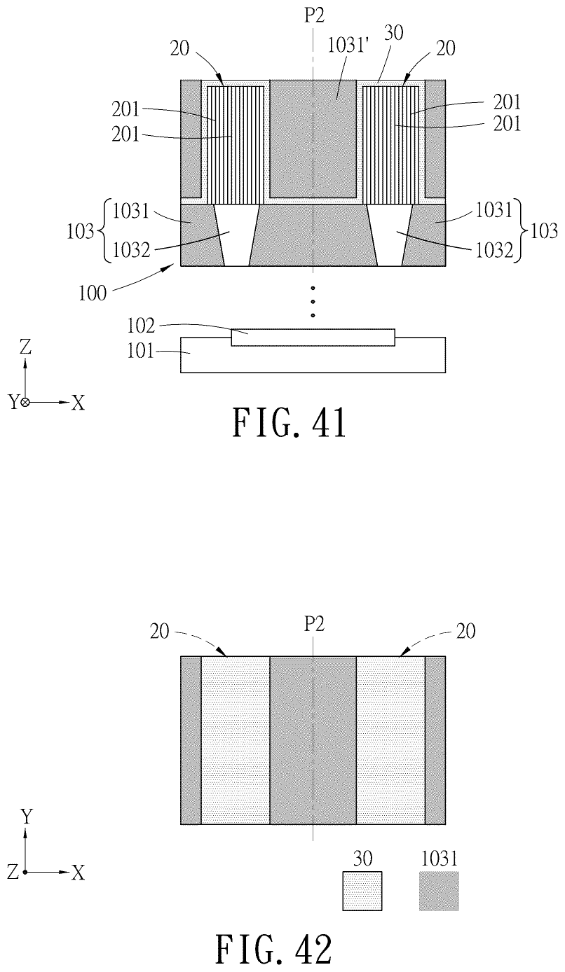

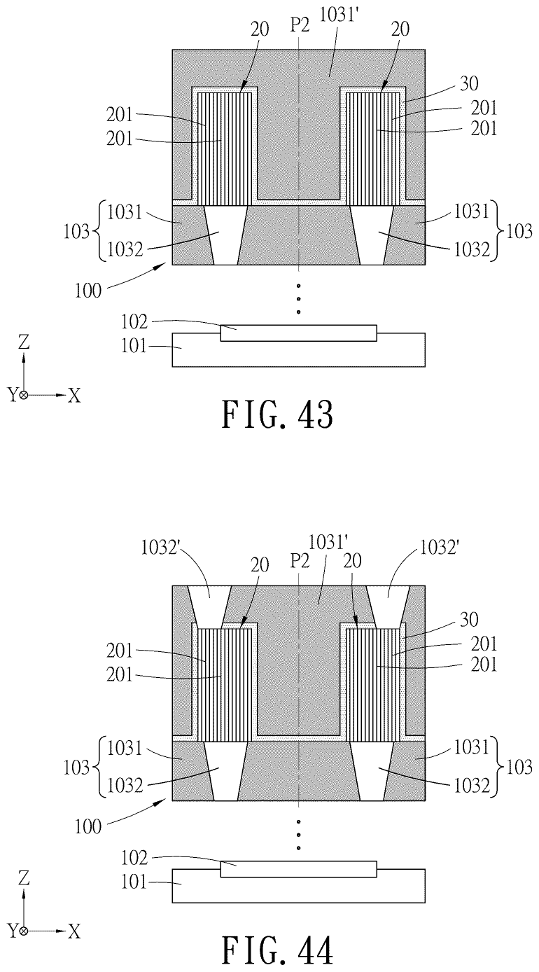

FIGS. 40 and 41 respectively illustrate two possible intermediate stages of step S05 in accordance with some embodiments. FIGS. 40 and 41 are diagrams respectively similar to FIGS. 29 and 30, except that FIGS. 40 and 41 show two structures subsequent to FIG. 38. In FIG. 40, the protection layer 30 is formed over the conductive features 20 to maintain the conductive features 20 on the base structure 100, and two sides of each of the conductive features 20 in the X direction are both directly in contact with the protection layer 30. FIG. 42 is a top schematic top-view diagram of FIG. 41 for illustrating the intermediate stage subsequent to FIG. 39 in accordance with some embodiments. FIG. 43 is a diagram similar to FIG. 32 for illustrating an intermediate stage of step S05 subsequent to FIG. 41 in accordance with some embodiments.

FIG. 44 illustrates a structure obtained in step S06 in accordance with some embodiments. FIG. 44 is a diagram similar to FIG. 33, except that FIG. 44 shows a structure subsequent to FIG. 43, and illustrate that, in step S06, two conductive feature 1032′ are formed to penetrate through the low-k dielectric layer 1031′ and the protection layer 30 and to be respectively connected to the conductive features 20 that are located therebeneath, and none of the conductive features 1032′ is connected to the patterned metal layer 92 (see FIG. 36) since the patterned metal layer 92 (see FIG. 36) is fully removed. In some embodiments not shown, the number of the conductive features 1032′ (each extending through the low-k dielectric layer 1031′ and the protection layer 30) may be more than two, and two of the conductive features 1032′ may both be connected to only one of the conductive features 20. It is noted that, for a better understanding, referring to FIGS. 34 to 37, when each of the examples illustrated in FIGS. 34 to 37 is cut by an imaginary plane (P2) and only a portion of each example that is located at a left side of the imaginary plane (P2) remains, the structure above the base structure 100 in each of FIGS. 34 to 37 may become nearly the same as that in a corresponding one of FIGS. 16, 17, 20 and 21 (e.g., a distance between each of the conductive features 1032 and an adjacent one of the sidewall surfaces 920 in the X direction is different).

In summary, by replacing conventional metals (e.g., copper) with 2D material layers, line resistance performance may be lowered and the contact resistance of the conductive feature(s) 20 or 40 with any one of the conductive features 1032 or 1032′ may be reduced. In addition, by virtue of the protection layer 30 maintaining and positioning the conductive feature(s) 20 or 40 on the base structure 100 and by virtue of the protection layer 30 preventing the 2D material layers 201 from water or damage and protecting the 2D material layers 201 from oxidation, the interconnect structure is less prone to malfunctions.

In accordance with some embodiments of the present disclosure, a method for manufacturing an interconnect structure includes: forming a patterned metal layer on an upper surface of a base structure, a first conductive feature of the base structure being exposed from the patterned metal layer, the patterned metal layer having a sidewall surface extending in a first direction transverse to the upper surface of the base structure; forming a second conductive feature from the sidewall surface of the patterned metal layer, forming the second conductive feature including sequentially forming two-dimensional (2D) material layers that are arranged in a second direction transverse to the first direction; after forming the second conductive feature, performing a removing process to remove at least a portion of the patterned metal layer; and after the removing process, forming a protection layer over the second conductive feature to maintain the second conductive feature on the base structure.

In accordance with some embodiments of the present disclosure, the second conductive feature includes graphene, intercalated graphene, N-doped graphene, O-doped graphene, modified graphene, hexagonal boron nitride (h-BN), intercalated h-BN, N-doped h-BN, O-doped h-BN, modified h-BN, borocarbonitride (BCN), transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, or combinations thereof.

In accordance with some embodiments of the present disclosure, the 2D material layers (201) include graphene, hexagonal boron nitride (h-BN), transition-metal dichalcogenide (TMD), germanane, Ni₃(2,3,6,7,10,11-hexaiminotriphenylene)₂ (Ni₃(HITP)₂), 2D metal, 2D alloy, or combinations thereof.

In accordance with some embodiments of the present disclosure, forming the second conductive feature further includes performing a treatment to the 2D material layers. The treatment is one of a plasma treatment, a chemical vapor deposition, a soaking treatment, a supercritical fluid treatment, or combinations thereof.

In accordance with some embodiments of the present disclosure, the treatment is performed to introduce an intercalant into spaces among the 2D material layers, the intercalant including metal ions, an organic compound, an inorganic compound, a macromolecule, or combinations thereof.

In accordance with some embodiments of the present disclosure, the metal ions include lithium ions, potassium ions, caesium ions, sodium ions, or combinations thereof.

In accordance with some embodiments of the present disclosure, the organic compound includes benzene, pyridine, furan, catechol, or combinations thereof.

In accordance with some embodiments of the present disclosure, the inorganic compound includes FeCl₃, MoCl₅, AuCl₃, CuCl₂, H₂SO₄, AlCl₃, Br₂, Cl₂, HNO₃, or combinations thereof.

In accordance with some embodiments of the present disclosure, the macromolecule includes polymethyl methacrylate, polymethyl methacrylate oligomer, polystyrene, polystyrene oligomer, polycaprolactam, polycaprolactam oligomer, or combinations thereof.

In accordance with some embodiments of the present disclosure, the treatment is performed to graft functional groups to the 2D material layers, the functional groups including sulfate groups, phosphate groups, carboxyl groups, nitrate groups, amino groups, amine groups, or combinations thereof.

In accordance with some embodiments of the present disclosure, the patterned metal layer includes cobalt, ruthenium, molybdenum, tungsten, titanium, tantalum, nickel, copper, alloys thereof, or combinations thereof.

In accordance with some embodiments of the present disclosure, the protection layer includes a liner material, a barrier material, or a combination thereof. The liner material is selected from cobalt, ruthenium, manganese, zinc, zirconium, tungsten, molybdenum, osmium, iridium, aluminum, iron, nickel, alloys thereof, nitrides thereof, oxides thereof, or combinations thereof. The barrier material is selected from aluminum nitride, aluminum oxide, silicon oxide, silicon oxycarbide, silicon oxycarbonitride, or combinations thereof.

In accordance with some embodiments of the present disclosure, the method further includes: forming an adhesive layer between the patterned metal layer and the base structure, the adhesive layer including titanium, tantalum, cobalt, ruthenium, titanium nitride, tantalum nitride, tungsten carbide, or combinations thereof.

In accordance with some embodiments of the present disclosure, a method for manufacturing an interconnect structure includes: forming a patterned metal layer on an upper surface of a base structure, the patterned metal layer having two sidewall surfaces which are spaced apart from each other in a first direction; forming two conductive features respectively from the two sidewall surfaces of the patterned metal layer, each of the two conductive features including two-dimensional (2D) layers; after forming the two conductive features, performing a removing process to remove at least a portion of the patterned metal layer; and after the removing process, forming a protection layer over the two conductive features to maintain the two conductive features on the base structure.

In accordance with some embodiments of the present disclosure, the two conductive features are located between the two sidewall surfaces of the patterned metal layer in the first direction, and are connected to each other.

In accordance with some embodiments of the present disclosure, the two conductive features are located between the two sidewall surfaces of the patterned metal layer in the first direction, and are separated from each other.

In accordance with some embodiments of the present disclosure, the two sidewall surfaces of the patterned metal layer are located between the two conductive features in the first direction.

In accordance with some embodiments of the present disclosure, in the removing process, the patterned metal layer is fully removed.

In accordance with some embodiments of the present disclosure, the protection layer is formed over the two conductive features and a remaining portion of the patterned metal layer.

In accordance with some embodiments of the present disclosure, an interconnect structure includes: a base structure having an upper surface and a first conductive feature; a second conductive feature formed on the first conductive feature, and including two-dimensional (2D) material layers, the second conductive feature having a downward surface connected to the upper surface of the base structure, an upward surface opposite to the downward surface, and an interconnection surface which interconnects the upward surface and the downward surface; a protection layer formed over the second conductive feature to maintain the second conductive feature on the base structure; and a metal material formed on the interconnection surface of the second conductive feature, and located between the protection layer and the second conductive feature, the metal material being in a form of a continuous layer, discontinuous layer or particles.

In accordance with some embodiments of the present disclosure, a method for manufacturing an interconnect structure includes: forming a patterned metal layer on an upper surface of a base structure, the patterned metal layer having two sidewall surfaces which are spaced apart from each other in a first direction; forming two conductive features respectively from the two sidewall surfaces of the patterned metal layer, each of the two conductive features including two-dimensional (2D) layers; after forming the two conductive features, performing a removing process to remove a first portion of the patterned metal layer, a second portion of the patterned metal layer remaining on at least one of the two conductive features; and after the removing process, forming a protection layer over the two conductive features and the second portion of the patterned metal layer to maintain the two conductive features and the second portion of the patterned metal layer on the base structure.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a patterned metal layer on an upper surface of a base structure, a first conductive feature of the base structure being exposed from the patterned metal layer, the patterned metal layer having a sidewall surface extending in a first direction transverse to the upper surface of the base structure;
forming a second conductive feature from the sidewall surface of the patterned metal layer, forming the second conductive feature including sequentially forming two-dimensional material layers that are arranged in a second direction transverse to the first direction;
after forming the second conductive feature, performing a removing process to remove at least a portion of the patterned metal layer; and
after the removing process, forming a protection layer over the second conductive feature to maintain the second conductive feature on the base structure.

2. The method as claimed in claim 1, wherein the second conductive feature includes graphene, intercalated graphene, N-doped graphene, O-doped graphene, modified graphene, hexagonal boron nitride (h-BN), intercalated h-BN, N-doped h-BN, O-doped h-BN, modified h-BN, borocarbonitride (BCN), transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, or combinations thereof.

3. The method as claimed in claim 1, wherein the 2D material layers include graphene, hexagonal boron nitride (h-BN), transition-metal dichalcogenide (TMD), germanane, Ni₃(2,3,6,7,10,11-hexaiminotriphenylene)₂ (Ni₃(HITP)₂), 2D metal, 2D alloy, or combinations thereof.

4. The method as claimed in claim 1, wherein forming the second conductive feature further includes performing a treatment to the 2D material layers, the treatment being one of a plasma treatment, a chemical vapor deposition, a soaking treatment, a supercritical fluid treatment, or combinations thereof.

5. The method as claimed in claim 4, wherein the treatment is performed to introduce an intercalant into spaces among the 2D material layers, the intercalant including metal ions, an organic compound, an inorganic compound, a macromolecule, or combinations thereof.

6. The method as claimed in claim 5, wherein the metal ions include lithium ions, potassium ions, caesium ions, sodium ions, or combinations thereof.

7. The method as claimed in claim 5, wherein the organic compound includes benzene, pyridine, furan, catechol, or combinations thereof.

8. The method as claimed in claim 5, wherein the inorganic compound includes FeCl₃, MoCl₅, AuCl₃, CuCl₂, H₂SO₄, AlCl₃, Br₂, Cl₂, HNO₃, or combinations thereof.

9. The method as claimed in claim 5, wherein the macromolecule includes polymethyl methacrylate, polymethyl methacrylate oligomer, polystyrene, polystyrene oligomer, polycaprolactam, polycaprolactam oligomer, or combinations thereof.

10. The method as claimed in claim 4, wherein the treatment is performed to graft functional groups to the 2D material layers, the functional groups including sulfate groups, phosphate groups, carboxyl groups, nitrate groups, amino groups, amine groups, or combinations thereof.

11. The method as claimed in claim 1, wherein the patterned metal layer includes cobalt, ruthenium, molybdenum, tungsten, titanium, tantalum, nickel, copper, alloys thereof, or combinations thereof.

12. The method as claimed in claim 1, wherein
the protection layer includes a liner material, a barrier material, or a combination thereof,
the liner material is selected from cobalt, ruthenium, manganese, zinc, zirconium, tungsten, molybdenum, osmium, iridium, aluminum, iron, nickel, alloys thereof, nitrides thereof, oxides thereof, or combinations thereof, and
the barrier material is selected from aluminum nitride, aluminum oxide, silicon oxide, silicon oxycarbide, silicon oxycarbonitride, or combinations thereof.

13. The method as claimed in claim 1, further comprising:
forming an adhesive layer between the patterned metal layer and the base structure, the adhesive layer including titanium, tantalum, cobalt, ruthenium, titanium nitride, tantalum nitride, tungsten carbide, or combinations thereof.

14. A method for manufacturing an interconnect structure, comprising:
forming a patterned metal layer on an upper surface of a base structure, the patterned metal layer having two sidewall surfaces which are spaced apart from each other in a first direction;
forming two conductive features respectively from the two sidewall surfaces of the patterned metal layer, each of the two conductive features including two-dimensional layers;
after forming the two conductive features, performing a removing process to remove at least a portion of the patterned metal layer; and
after the removing process, forming a protection layer over the two conductive features to maintain the two conductive features on the base structure.

15. The method as claimed in claim 14, wherein the two conductive features are located between the two sidewall surfaces of the patterned metal layer in the first direction, and are connected to each other.

16. The method as claimed in claim 14, wherein the two conductive features are located between the two sidewall surfaces of the patterned metal layer in the first direction, and are separated from each other.

17. The method as claimed in claim 14, wherein the two sidewall surfaces of the patterned metal layer are located between the two conductive features in the first direction.

18. The method as claimed in claim 14, wherein, in the removing process, the patterned metal layer is fully removed.

19. The method as claimed in claim 14, wherein the protection layer is formed over the two conductive features and a remaining portion of the patterned metal layer.

20. An interconnect structure, comprising:
a base structure having an upper surface and a first conductive feature;
a second conductive feature formed on the first conductive feature, and including two-dimensional material layers, the second conductive feature having a downward surface connected to the upper surface of the base structure, an upward surface opposite to the downward surface, and an interconnection surface which interconnects the upward surface and the downward surface;
a protection layer formed over the second conductive feature to maintain the second conductive feature on the base structure; and
a metal material formed on the interconnection surface of the second conductive feature, and located between the protection layer and the second conductive feature, the metal material being in a form of a continuous layer, discontinuous layer or particles.
